(19) United States
(12) Patent Application Publication
(10) Pub. No.: US 2026/0366135 A1
(43) Pub. Date: Nov. 19, 2026

(54) A LAMINATED ARTICLE COMPRISING A CHROMIUM LAYER AND METHOD OF MANUFACTURING THEREOF

(71) Applicant: AMCOR FLEXIBLES NORTH AMERICA, INC., Neenah, WI (US)

(72) Inventors: Galina OURIEVA, Amougies (BE); Wolfgang LOHWASSER, Gailingen (DE); Peter ETTRIDGE, Worcester (GB); Roy CHRISTOPHERSON, Shrivenham (GB)

(21) Appl. No.: 19/121,780

(22) PCT Filed: Nov. 3, 2022
(86) PCT No.: PCT/US2022/048857

§ 371 Date: Apr. 16, 2025

(51) Int. Cl. C23C 14/20; B32B 7/14; B32B 27/08

(52) U.S. Cl. CPC C23C 14/20; B32B 7/14; B32B 27/08; B32B 2255/10; B32B 2255/205; B32B 2307/7376

(57) ABSTRACT

An article is disclosed. The article includes a first substrate. The article further includes a chromium layer disposed on the first substrate. The article further includes a second substrate disposed adjacent to the chromium layer opposite to the first substrate. The article further includes an adhesive layer at least partially disposed between the chromium layer and the second substrate. The adhesive layer bonds the second substrate to the chromium layer.

### TECHNICAL FIELD

The present application relates generally to an article and a method of manufacturing the article.

### BACKGROUND

An article may include a first substrate (e.g., a polymeric film) bonded to a second substrate by an adhesive. In various applications, the article may be exposed and subject to attack from chemicals, moisture, temperature, and the like. Therefore, it may be essential that the bond between the first substrate and the second substrate is maintained.

Currently, specific chemistries of the first and second substrates and/or the adhesive may have to be selected in order to maintain the bond between the first substrate and the second substrate. The specific chemistries of the first and second substrates and/or the adhesive may need to be selected during a designing stage of the article.

Therefore, there is a need of an article that allows reliable bonding of the second substrate with the first substrate via a wide range of adhesive chemistries and technologies, applied by a wide range of technologies, while maintaining the bond between the first and second substrates when exposed to chemicals, moisture, temperature, and the like.

### SUMMARY

An article including a first substrate and a second substrate has been developed. The article may enable a reliable bonding of the second substrate to the first substrate via an adhesive selected from a wide range of adhesive chemistries. Advantageously, the article may allow maintenance of the bond between the first substrate and the second substrate when the article is exposed to chemicals, moisture, temperature, and the like.

One embodiment of the present disclosure is an article. The article includes a first substrate. The article further includes a chromium layer disposed on the first substrate. The chromium layer includes at least 90% chromium, by weight. The article further includes a second substrate disposed adjacent to the chromium layer opposite to the first substrate. The article further includes an adhesive layer at least partially disposed between the chromium layer and the second substrate. The adhesive layer bonds the second substrate to the chromium layer.

The chromium layer may promote bonding of the second substrate to the first substrate via the adhesive layer. Furthermore, the chromium layer may be resistant to corrosion, chemicals, high temperature, humidity, and the like. As a result, the chromium layer may allow the bonding of the first substrate with the second substrate while maintaining the bond between the first substrate and the second substrate, particularly when exposed to chemicals, moisture, temperature, and the like. Advantageously, the chromium layer may facilitate bonding of the second substrate to the first substrate via a wide range of adhesive chemistries and technologies. In other words, the adhesive layer may include an adhesive selected from a wide range of adhesive chemistries.

In some embodiments, the first substrate is a polymeric film, and the polymeric film includes at least one of polypropylene (PP), polyethylene (PE), polyamide (PA), polyphenylene sulfide (PPS), ethylene chlorotrifluoroethylene (ECTFE), polyvinylidene fluoride (PVdF), and polyethylene terephthalate (PET).

In some embodiments, the first substrate is oriented. The first substrate may be oriented if the first substrate is the polymeric film. Orientation of the first substrate may improve physical properties thereof. For example, an oriented polymeric film may include a greater tensile strength as compared to an equivalent non-oriented polymeric film.

In some embodiments, the first substrate includes a metal, a glass, a glass fiber, or a paper.

In some embodiments, the chromium layer is vapor deposited on the first substrate. For example, the chromium layer may be deposited on the first substrate via physical vapor deposition (PVD).

In some embodiments, the chromium layer includes a thickness from 1 nanometer to 200 nanometers.

In some embodiments, the chromium layer includes a thickness from 1 nanometer to 9 nanometers. Surprisingly, the chromium layer may possess desirable adhesion promotion properties and corrosion resistant properties while being very thin (i.e., including a thickness from 1 nanometer to 9 nanometers).

In some embodiments, the first substrate includes a thickness from 5 microns to 550 microns.

In some embodiments, the adhesive layer is patterned.

In some embodiments, the adhesive layer includes an adhesive. The adhesive includes at least one of epoxy, polyurethane (PU), polyethylene (PE), copolymers of polyethylene, polypropylene (PP), polysulfide (PS), acrylate, and silicone. Advantageously, the chromium layer of the article may allow the adhesive to be selected from a wide variety of chemistries.

In some embodiments, the adhesive layer includes at least one of polyethylene (PE) and polypropylene (PP). At least one of the polyethylene (PE) and the polypropylene (PP) of the adhesive layer is modified with maleic anhydride. Modification of the polyethylene (PE) and the polypropylene (PP) with maleic anhydride may improve adhesion properties of the adhesive layer.

In some embodiments, the chromium layer includes at least one of trivalent chromium and metallic chromium. Trivalent chromium and metallic chromium may be non-toxic, and therefore safe to use.

In some embodiments, the chromium layer is free of hexavalent chromium. Hexavalent chromium may be toxic, as well as carcinogenic (IARC Group 1). Therefore, hexavalent chromium may preferably be omitted from the chromium layer.

Another embodiment of the present disclosure is a method of manufacturing an article. The method includes providing a first substrate. The method further includes depositing a chromium layer on the first substrate. The chromium layer includes at least 90% chromium, by weight. The method further includes bonding a second substrate to the chromium layer opposite to the first substrate via an adhesive layer.

In some embodiments, depositing the chromium layer further includes vapor depositing chromium.

There are several aspects of the present subject matter which may be embodied separately or together. These aspects may be employed alone or in combination with other aspects of the subject matter described herein, and the description of these aspects together is not intended to preclude the use of these aspects separately or the claiming of such aspects separately or in different combinations.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic cross-sectional view of an article in accordance with an embodiment of the present disclosure;

FIG. 2 is a flowchart depicting various steps of a method of manufacturing an article in accordance with an embodiment of the present disclosure; and

FIG. 3 is a graph depicting reflection ratios of various articles in accordance with embodiments of the present disclosure that underwent a damp heat test.

The figures are not necessarily to scale. Like numbers used in the figures refer to like components. It will be understood, however, that the use of a number to refer to a component in a given figure is not intended to limit the component in another figure labeled with the same number.

### DETAILED DESCRIPTION

The present application describes an article. The article includes a first substrate and a chromium layer disposed on the first substrate. The chromium layer includes at least 90% chromium, by weight. The article further includes a second substrate disposed adjacent to the chromium layer opposite to the first substrate. The article further includes an adhesive layer partially or fully disposed between the chromium layer and the second substrate. The adhesive layer bonds the second substrate to the chromium layer. The adhesive layer may be directly connected to the chromium layer.

The chromium layer may promote bonding of the second substrate to the first substrate via the adhesive layer. Furthermore, the chromium layer may be resistant to corrosion, chemicals, high temperature, humidity, and the like. As a result, the chromium layer may allow the bonding of the first substrate with the second substrate while maintaining the bond between the first substrate and the second substrate, particularly when exposed to chemicals, moisture, temperature, and the like. Advantageously, the chromium layer may facilitate bonding of the second substrate to the first substrate via a wide range of adhesive chemistries and technologies. In other words, the adhesive layer may include an adhesive selected from a wide range of adhesive chemistries.

As used herein, the terms “first” and “second” are used as identifiers. Therefore, such terms should not be construed as limiting of this disclosure. The terms “first” and “second” when used in conjunction with a feature or an element can be interchanged throughout the embodiments of this disclosure.

As used herein, the term “film” is a material with a very high ratio of a length and a width to a thickness. A film has two major surfaces defined by a length and a width. Films typically have good flexibility and can be used for a wide variety of applications. Films may also be of suitable thickness and/or material composition such that they are flexible, semi-rigid, or rigid. Films may be described as monolayer or multilayer.

As used herein, the term “article” is a composition of multiple components connected to each other. Each of the components or substrates of the article may have independent shape or size. For example, an article may have a component that is a film and another article that has a three dimensionally irregular shape. As described herein, the articles comprise components of a first substrate, a second substrate, a chromium layer and an adhesive layer. As used herein, the term “substrate” refers to a component that may of any type, and comprises at least one surface to which another component is attached.

Unless specified or limited otherwise, the terms “attached,” “connected,” “coupled,” and variations thereof, are used broadly and encompass both direct and indirect attachments, connections, and couplings. The terms “directly attached,” “directly connected”, and variations thereof, of used to specify direct attachment.

As used herein, the term “adjacent” refers to being near, close, contiguous, adjoining, or neighboring in proximity. It includes, but is not limited to, being reasonably close to or in the vicinity of as well as touching, having a common boundary or having direct contact.

As used herein, the term “polymer” or “polymeric” refers to a material which is the product of a polymerization or copolymerization reaction of natural, synthetic, or natural and synthetic monomers and/or comonomers, and is inclusive of homopolymers, copolymers, terpolymers, etc. The term “polymer film” or “polymeric film” refers to a film made from such material.

As used herein, the term “polyethylene” refers to a homopolymer or copolymer having at least one ethylene monomer linkage within the repeating backbone of the polymer. The ethylene linkage can be represented by the general formula: [CH2-CH2]ₙ. Polyethylenes may be formed by any method known to those skilled in the art.

As used herein, the term “modified” refers to a chemical derivative, e.g., one having any form of anhydride functionality, such as anhydride of maleic acid, crotonic acid, citraconic acid, itaconic acid, fumaric acid, etc., whether grafted onto a polymer, copolymerized with a polymer, or otherwise functionally associated with one or more polymers, and is also inclusive of derivatives of such functionalities, such as acids, esters, and metal salts derived therefrom. Another example of a common modification is acrylate modified polyolefins.

As used herein, the term “polyphenylene sulfide” or “PPS” refers to an organic polymer including aromatic rings linked by sulfides.

As used herein, the term “ethylene chlorotrifluoroethylene” or “ECTFE” refers to a semi-crystalline fluoropolymer. Ethylene chlorotrifluoroethylene is a copolymer of ethylene and chlorotrifluoroethylene.

As used herein, the term “polyvinylidene fluoride” or “PVDF” refers to a highly non-reactive thermoplastic fluoropolymer. PVDF may be produced by the polymerization of vinylidene difluoride.

As used herein, the term “adhesive layer” refers to a layer which has a primary function of bonding two adjacent layers together. An adhesive layer may be positioned between two layers of a multilayer film to maintain the two layers in position relative to each other and prevent undesirable delamination. An adhesive layer may be positioned between two components of an article to maintain the two components in position relative to each other and prevent undesirable delamination. Unless otherwise indicated, an adhesive layer can have any suitable composition that provides a desired level of adhesion with the one or more surfaces in contact with the adhesive layer material.

As used herein, the term “barrier property” refers to a property of a material or layer which controls a permeable element of a film, sheet, web, package, etc., against aggressive agents, and includes, but is not limited to, oxygen barrier, moisture (e.g., water, humidity, etc.) barrier, chemical barrier, and the like. The term “barrier film” refers to films that provide such barrier properties.

As used herein, the term “relative humidity” or “RH” refers to the measure of water vapor in the air relative to the temperature of the air.

As used herein, “at least one of A and B” should be understood to mean “only A, only B, or both A and B”.

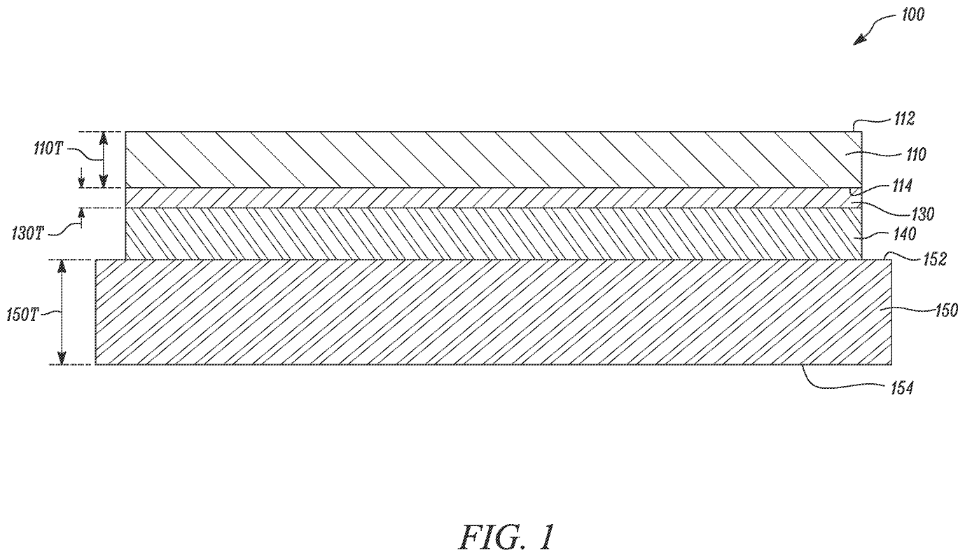

FIG. 1 shows a schematic cross-sectional view of an article 100 in accordance with an embodiment of the present disclosure.

Article 100 includes a first substrate 110. First substrate 110 may include any suitable material, such as a metal (e.g., aluminum, steel, etc.), a glass, a plastic, and the like. The material of the first substrate may be reinforced, unreinforced, transparent, and/or foamed (foam-based). In some embodiments, first substrate 110 may be a polymer film.

First substrate 110 may further include a first major surface 112 and a second major surface 114 opposite to first major surface 112. First substrate 110 may further include a thickness 110T. Thickness 110T may be defined as the distance between first major surface 112 and second major surface 114 of first substrate 110. Thickness 110T may selected depending upon desired application attributes of article 100. In some embodiments, thickness 110T may be from 5 microns to 550 microns. In some embodiments, thickness 110T may be from 6 microns to 100 microns.

As discussed above, first substrate 110 may be a polymeric film. The polymeric film may include any suitable polymer that is formed by polymerization reaction of natural, synthetic, or natural and synthetic ingredients, including homopolymers, copolymers, terpolymers, etc. In some embodiments, the polymeric film may include at least one of polypropylene (PP), polyethylene (PE), polyamide (PA), polyphenylene sulfide (PPS), ethylene chlorotrifluoroethylene (ECTFE), polyvinylidene fluoride (PVdF), and polyethylene terephthalate (PET).

The polyethylene (PE) of the polymeric film may include at least one of ultra-low-density polyethylene (ULDPE), low density polyethylene (LDPE), linear low-density polyethylene (LLDPE), medium density polyethylene (MDPE), linear medium density polyethylene (LMDPE), high density polyethylene (HDPE), ethylene vinyl acetate (EVA), and copolymers of polyethylene (PE). For example, copolymers of polyethylene (PE) may include polyethylene modified with maleic anhydride (MAH), ethyl acetoacetate (EAA), etc.

In some embodiments, first substrate 110 may be oriented. First substrate 110 may be oriented if it is the polymeric film. First substrate 110 may be biaxially oriented, machine direction oriented, or transverse direction oriented, as per desired application attributes. First substrate 110 may be oriented to improve its mechanical, barrier, and/or porosity characteristics.

Article 100 further includes a chromium layer 130 disposed on first substrate 110. Chromium layer 130 may be at least partially disposed on first substrate 110. As shown in FIG. 1, chromium layer 130 may be disposed on second major surface 114 of first substrate 110. Chromium layer 130 includes at least 90% chromium, at least 95% chromium or at least 99% chromium, by weight. In other words, at least 90 or 95 or 99 weight percentage of chromium layer 130 is of chromium. In some embodiments, chromium layer 130 may include 100% chromium, by weight.

In some embodiments, chromium layer 130 may include at least one of trivalent chromium and metallic chromium. Trivalent chromium and metallic chromium may be non-toxic, and therefore safe to use. However, hexavalent chromium may be toxic as well as carcinogenic (IARC Group 1). Therefore, in some embodiments, chromium layer 130 may be free of hexavalent chromium.

Chromium layer 130 may be disposed on first substrate 110 by any suitable method and technique. In some embodiments, chromium layer 130 may be vapor deposited on first substrate 110. For example, chromium layer 130 may be deposited on first substrate 110 via physical vapor deposition (PVD).

Article 100 further includes a second substrate 150 disposed adjacent to chromium layer 130 opposite to the first substrate 110. Second substrate 150 may include any suitable material, such as a metal (e.g., aluminum, steel, etc.), a glass, a plastic, and the like. In some embodiments, second substrate 150 may include a glass fiber. The material of the second substrate may be reinforced, unreinforced, transparent, and/or foamed (foam-based). In some embodiments, second substrate 150 may include a polymer film.

Second substrate 150 may further include a first major surface 152 and a second major surface 154 opposite to first major surface 152. As shown in FIG. 1, first major surface 152 of second substrate 150 may face chromium layer 130.

Second substrate 150 may further include a thickness 150T. Thickness 150T may be defined between first major surface 152 and second major surface 154 of second substrate 150. Thickness 150T may be from 5 microns to 550 microns. Second substrate 150 may be a film, a sheet, or a non-planar shaped substrate. For example, second substrate 150 may be an injection molded part.

Article 100 further includes an adhesive layer 140 at least partially disposed between chromium layer 130 and second substrate 150. Adhesive layer 140 bonds second substrate 150 to chromium layer 130. In some embodiments, adhesive layer 140 may be substantially continuous. In some other embodiments, adhesive layer 140 may be patterned.

Adhesive layer 140 may include an adhesive that may be selected from a wide variety of suitable adhesives. In some embodiments, adhesive layer 140 may include an adhesive including at least one of epoxy, polyurethane (PU), polyethylene (PE), polypropylene (PP), polysulfide (PS), acrylate, and silicone. Furthermore, at least one of the polyethylene (PE) and the polypropylene (PP) of adhesive layer 140 may be modified with maleic anhydride. Modification of the polyethylene (PE) and/or the polypropylene (PP) of the adhesive with maleic anhydride may improve an adhesion strength of adhesive layer 140.

Chromium layer 130 may facilitate bonding of second substrate 150 to first substrate 110. In some examples, chromium layer 130 may promote adhesion of second substrate 150 to first substrate 110 via a wide range of adhesives, applied by a wide range of technologies, while providing stability in high temperature and humidity.

Furthermore, chromium layer 130 may be resistant to corrosion, hydrolysis, thermal degradation, and the like. As a result, article 100 may be suitable for use in harsh conditions, including exposure to attack from chemicals, moisture, and temperature. Although an aluminum layer provides for good adhesion, it may be susceptible to corrosion when exposed to water, particularly with elevated temperatures. Chromium layer 130, on the other hand, may be stable when exposed to moisture and chemically stable, thereby overcoming the corrosion limitations of aluminum.

Chromium layer 130 may further include a thickness 130T. In some embodiments, thickness 130T may be from 1 nanometer to 200 nanometers. In some embodiments, thickness 130T may be from 1 nanometer to 9 nanometers. It has been surprisingly found that chromium layer 130 can provide desirable adhesion promotion properties and corrosion resistant properties while being very thin (i.e., having thickness 130T from 1 nanometer to 9 nanometers).

Chromium may also provide a high binding strength with oxygen. Advantageously, in cases where chromium interfaces with glass (including silica), chromium oxide formed by oxidation of chromium may have equivalent binding energy as silicon oxide.

Chromium may further de-passivate many material surfaces. In other words, chromium may reduce (take oxygen from) a substrate directly attached to chromium layer 130. Moreover, during use of article 100, the chromium of chromium layer 130 may form a chromium oxide layer (not shown).

Furthermore, chromium layer 130 may be used to functionalize otherwise difficult surfaces to adhere to. For example, chromium layer 130 may functionalize homopolymer polypropylene (i.e., the first substrate may comprise a homopolymer polypropylene). Homopolymer polypropylene is a desirable material to use due to its durability, tensile strength, and low cost. Functionalizing a homopolymer polypropylene film with chromium layer 130 may form a surface compatible with a wide range of adhesives with long term stability. This may be beneficial for the adhesive tape industry. For example, chromium layer 130 may allow an adhesive chemist to focus their efforts on the functionality of the adhesive in development toward an intended surface, rather than having to be concerned about the adhesion to a carrier tape. Furthermore, the long term stability of chromium may benefit products having lifespans of tens of years.

Chromium may further provide advantages as a high temperature corrosion resistant primer for electronic applications. High performance polymer-based coatings are often used to protect a range of substrates (such as metals and high temperature resistant polymers) from corrosion and provide a stable primer layer thereon. However, upon prolonged thermal exposure, such polymeric primers and protective layers are prone to degradation, thereby compromising their corrosion protection, adhesive, and cohesive properties. Chromium may remain unaffected by heat, cold, moisture and corrosion attack. Therefore, a chromium layer may be an ideal “universal” corrosion and thermally resistant primer layer.

Packaged aggressive goods such as cosmetics, agrochemicals, pharmaceuticals, industrial adhesives, and the like, may cause issues of package integrity through corrosion of barrier layers. For example, cosmetics may contain high levels of alcohols, oils, ammonia, peroxides, etc. which attach many components of the sachet in which they may be packaged. Further, industrial adhesive packs may contain unreacted amines, isocyanates, epoxies, benzene derivatives, inorganic acids, bases, solvents, and a combination of a strong acidic or strong alkaline environment, with organic solvents and moisture. These may cause corrosion issues to unprotected barrier layers. A chromium layer, such as chromium layer 130, may stabilize an interface between a sealant layer and a barrier layer of the packages, thereby maintaining pack integrity and optimizing adhesion of the sealant layer to it. The chemical resistance of chromium in a broad pH range may also add value in various applications, such as technical energy market, and pharmaceutical market, for example, in high pH liquids in the pharmaceutical cold formed blister packaging.

Chromium may also be beneficial in light blocking heat attenuation screens for greenhouses. Aggressive chemicals that are generally used in greenhouses, such as pesticides, fertilizers, etc., act to corrode polymer films metallized with an aluminum layer, even when the aluminum layer is overlacquered with a corrosion resistant lacquer or film. Corroded aluminum may turn into transparent aluminum oxide, which does not provide its primary function of light blocking. In the case of a laminate, corrosion will lead to delamination, or with a lacquered layer, loss of coating adhesion of the lacquer.

Chromium may be coated on polymers to provide corrosion-stable polymer coated screens having several benefits over laminates with aluminum foil. The corrosion-stable polymer coated screens may be lighter in weight as compared to the laminates with aluminum foil. Thus, the corrosion-stable polymer coated screens may be supported on lower cost and lighter weight assemblies.

The degree of light blocking may be varied by controlling the thickness of the chromium layer. The chromium layer may provide increased reflectivity of heat and/or cooling efficiency. The chromium layer may further provide increased resistance to environmental exposure.

A chromium layer may also be used in recycle-ready packaging structures. For example, the chromium layer may be deposited on an OPP substrate (first substrate) as a primer for a barrier coating, such as EVOH, SiOx, etc.

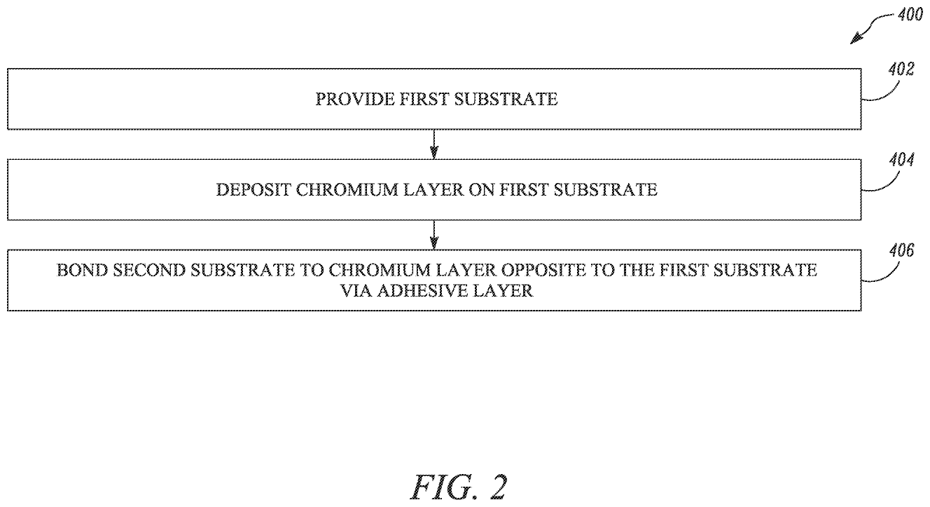

FIG. 2 shows a method 400 of manufacturing an article in accordance with an embodiment of the present disclosure. Method 400 may be used to manufacture article 100 of FIG. 1. Method 400 will be discussed with additional reference to FIG. 1.

At step 402, method 400 includes providing a first substrate. For example, method 400 may include providing first substrate 110.

At step 404, method 400 includes depositing a chromium layer on the first substrate. The chromium layer includes at least 90% chromium, at least 95% chromium or at least 99% chromium chromium, by weight. For example, method 400 may include depositing chromium layer 130 on first substrate 110.

At step 406, method 400 includes bonding a second substrate to the chromium layer opposite to the first substrate via an adhesive layer. For example, method 400 may include bonding second substrate 150 to chromium layer 130 opposite to first substrate 110 via adhesive layer 140.

In some embodiments, depositing the chromium layer may further include vapor depositing chromium. For example, depositing chromium layer 130 may further include vapor depositing chromium.

### Experimental Results

Various sealing webs were developed to carry out a climate ageing experiment. Climate ageing may be interchangeably referred to as “damp heat testing”.

Various polymeric films were heat laminated to an aluminum film having a maleic anhydride grafted polypropylene polymer coated thereon (MAH-PP/ALU) to form the sealing webs. Furthermore, various polymeric films were laminated to a metallized PET (i.e., PET deposited with an aluminum layer) via a polyurethane (PUR) based adhesive to form some of the sealing webs.

Comparative Examples 1~4 (CE1-CE4) included polymeric films deposited with aluminum, aluminum oxide, silicon oxide, and acrylic, respectively, and heat laminated to the MAH-PP/ALU structure. Examples 1 and 2 (E1 and E2) included polymeric films deposited with chromium and heat laminated to the MAH-PP/ALU structure.

Comparative Examples 5 and 6 (CE5 and CE6) included polymeric films deposited with aluminum and laminated to the metallized PET via the polyurethane (PUR) based adhesive. Example 3 (E3) included a polymeric film deposited with chromium and laminated to the metallized PET via the polyurethane (PUR) based adhesive.

The sealing webs of Examples 1-3 and Comparative Examples 1-6 were then subjected to damp heat at 85 degrees centigrade (°C) and 85% RH (relative humidity) for four weeks. Inspection of bond strength was done before and after the climate ageing. The bond strength of each of the sealing webs before and after the climate ageing is tabulated in Table 1 provided below.

TABLE 1
Bond Strength

| | | | Before | After |
|---|---|---|---|---|
| | | | Climate | Climate |
| | | | Ageing | Ageing |
| Lamination | | | Adhesion | Adhesion |
| Type | Example | Structure | (N/15 mm) | (N/15 mm) |
| Heat- | E1 | BOPP/Cr/MAH-PP/ALU | 4 | 8 |
| laminated | E2 | Extruded PP/Cr/MAH- | 12 | 12 |
| against MAH- | | PP/ALU | | |
| PP/ALU | CE1 | BOPP/Al/MAH-PP/ALU | 1.3 | 1.1 |
| | CE2 | OPP/SiOx/MAH-PP/ALU | 2.6 | 0.3 |
| | CE3 | PET/AlOx/MAH-PP/ALU | 3.8 | 2.9 |
| | CE4 | PET/PMMA/MAH-PP/ALU | 5.9 | 2.3 |
| Solvent- | E3 | BOPP/Cr/PUR/PET/ALU | 1.9 | 3.1 |
| based PUR | CE5 | BOPP/Al/PUR/PET/ALU | 1.5 | 0 |
| adhesive | CE6 | PET/Al/PUR/PET/ALU | 1.5 | 0.8 |
| lamination | | | | |

As depicted by Table 1, the sealing webs of Examples 1-3 performed very well after climate ageing, especially when compared to Comparative Examples 1-6. It was concluded that the chromium coating in Examples 1-3 provided the excellent adhesion performance.

In another experiment, adhesion of a chromium coating to OPP and PET substrates was evaluated before and after 4 weeks of damp heat exposure at 85 °C and 85% RH by means of tape test. Four OPP substrates were selected from various batches, which differed in e-beam line settings, substrate chemistry, and possessed a batch to batch variation. An excellent adhesion of the chromium coating to the OPP substrate and PET substrate was observed.

Visual optical and UV-visible spectroscopy evaluation before and after the damp heat testing supported the positive adhesion test results. No changes in the optical appearance and the gloss of the coating were observed.

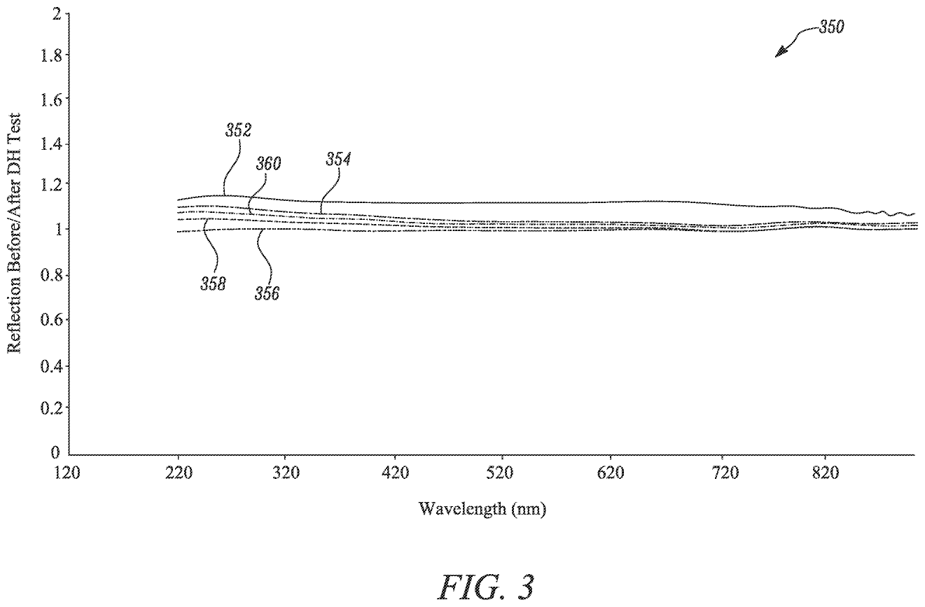

Results of a reflection test for all batches before and after 4 weeks of damp heat at 85 °C and 85% RH ageing test are shown in a graph 350 in FIG. 3. Specifically, graph 350 shows a reflection ratio for a chromated article taken from each batch. The reflection ratio is defined between a reflection value of the chromated article measured before the damp heat test and a reflection value of the chromated article measured after the damp heat test. The reflection ratios of the chromated OPP substrates from batches 1-4 are represented by curves 352, 354, 356, 358, respectively, in FIG. 3. Further, the reflection ratio of the chromated PET substrate is represented by a curve 360 in FIG. 3. As depicted by curves 352, 354, 356, 358, 360, the reflection ratios remained substantially close to 1 across the wavelength range from 220 nanometers to 900 nanometers. The reflective properties of the chromated articles remained substantially intact after undergoing the damp heat test.

These results further supported the finding that a robustness of the chromium coating was independent of the chromium deposition process (physical vapor deposition) conditions and accelerated ageing.

In a third experiment, an OPP substrate with a chromium coating and an OPP substrate with an aluminum coating were subjected to a sterilization ageing test (121 °C for 30 minutes) for testing their feasibility in retort and sterilization applications.

The OPP substrate with the aluminum coating, even when protected by a hydrolytically stable adhesive, lost its aluminum coating. On the other hand, the chromium coating of the OPP substrate with the chromium coating was perfectly preserved.

A similar test was then performed on a PET substrate. The PET substrate with the aluminum coating lost its aluminum coating. On the other hand, the chromium coating of the PET substrate with the chromium coating was perfectly preserved.

Each and every document cited in this present application, including any cross referenced, is incorporated in this present application in its entirety by this reference, unless expressly excluded or otherwise limited. The citation of any document is not an admission that it is prior art with respect to any embodiment disclosed in this present application or that it alone, or in any combination with any other reference or references, teaches, suggests, or discloses any such embodiment. Further, to the extent that any meaning or definition of a term in this present application conflicts with any meaning or definition of the same term in a document incorporated by reference, the meaning or definition assigned to that term in this present application governs.

Unless otherwise indicated, all numbers expressing sizes, amounts, ranges, limits, and physical and other properties used in the present application are to be understood as being preceded in all instances ay the term “about”. Accordingly, unless expressly indicated to the contrary, the numerical parameters set forth in the present application are approximations that can vary depending on the desired properties sought to be obtained by a person of ordinary skill in the art without undue experimentation using the teachings disclosed in the present application.

As used in the present application, the singular forms “a”, “an”, and “the” encompass embodiments having plural referents, unless the context clearly dictates otherwise. As used in the present application, the term “or” is generally employed in its sense including “and/or”, “unless” the context clearly dictates otherwise.

Spatially related terms, including but not limited to, “lower”, “upper”, “beneath”, “below”, “above”, “bottom” and “top”, if used in the present application, are used for ease of description to describe spatial relationships of an element(s) to another. Such spatially related terms encompass different orientations of the device in use or operation, in addition to the particular orientations depicted in the figures and described in the present application. For example, if an object depicted in the drawings is turned over or flipped over, elements previously described as below, or beneath other elements would then be above those other elements.

1. An article comprising:
a first substrate;
a chromium layer disposed on the first substrate, the chromium layer comprising at least 90% chromium, by weight;
a second substrate disposed adjacent to the chromium layer opposite to the first substrate; and
an adhesive layer comprising an adhesive comprising at least one of epoxy, polyurethane (PU), polysulfide (PS), acrylate, and silicone, and at least partially disposed between the chromium layer and the second substrate, wherein the adhesive layer bonds the second substrate to the chromium layer.

2. The article according to claim 1, wherein the first substrate is a polymeric film, and the polymeric film comprises at least one of polypropylene (PP), polyethylene (PE), polyamide (PA), polyphenylene sulfide (PPS), ethylene chlorotrifluoroethylene (ECTFE), polyvinylidene fluoride (PVdF), and polyethylene terephthalate (PET).

3. The article according to claim 2, wherein the first substrate is oriented.

4. The article according to claim 1, wherein the first substrate comprises a metal, a glass, a glass fiber, or a paper.

5. The article according to claim 1, wherein the chromium layer is vapor deposited on the first substrate.

6. The article according to claim 1, wherein the chromium layer comprises a thickness from 1 nanometer to 200 nanometers.

7. The article according to claim 6, wherein the chromium layer comprises a thickness from 1 nanometer to 9 nanometers.

8. The article according to claim 1, wherein the first substrate comprises a thickness from 5 microns to 550 microns.

9. The article according to claim 1, wherein the adhesive layer is patterned.

10. (canceled)

11. (canceled)

12. The article according to claim 1, wherein the chromium layer comprises at least one of trivalent chromium and metallic chromium.

13. The article according to claim 1, wherein the chromium layer is free of hexavalent chromium.

14. (canceled)

15. (canceled)
